(19) United States
(12) Patent Application Publication
(10) Pub. No.: US 2024/0111219 A1
(43) Pub. Date: Apr. 4, 2024

(54) WAVELENGTH CONTROL METHOD, LASER APPARATUS, AND METHOD FOR MANUFACTURING ELECTRONIC DEVICES

(71) Applicant: Gigaphoton Inc., Tochigi (JP)

(72) Inventors: Shigeto KISHIMOTO, Oyama-shi (JP); Hirotaka MIYAMOTO, Oyama-shi (JP)

(73) Assignee: Gigaphoton Inc., Tochigi (JP)

(21) Appl. No.: 18/539,324

(22) Filed: Dec. 14, 2023

Related U.S. Application Data
(63) Continuation of application No. PCT/JP2021/024921, filed on Jul. 1, 2021.

(51) Int. Cl. G03F 7/00; H01S 3/134

(52) U.S. Cl. CPC G03F 7/70575; G03F 7/70025; H01S 3/134

(57) ABSTRACT

A wavelength control method in a laser apparatus including a wavelength actuator configured to cyclically change the wavelength of pulse laser light output in the form of a burst includes reading data on a wavelength target value, determining from the data a first target wavelength and a second target wavelength shorter than the first target wavelength, and setting wavelengths of at least one first-period long wavelength pulse and at least one first-period short wavelength pulse contained in a first period at a start of a burst to a first set wavelength shorter than the first target wavelength and a second set wavelength longer than the second target wavelength, respectively, by using the first target wavelength and the second target wavelength to control the wavelength actuator.

### CROSS-REFERENCE TO RELATED APPLICATIONS

The present application is a continuation application of International Application No. PCT/JP2021/024921, filed on Jul. 1, 2021, the entire contents of which are hereby incorporated by reference.

### BACKGROUND

### 1. Technical Field

The present disclosure relates to a wavelength control method, a laser apparatus, and a method for manufacturing electronic devices.

### 2. Related Art

A semiconductor exposure apparatus is required to improve the resolution thereof as semiconductor integrated circuits are increasingly miniaturized and highly integrated. The semiconductor exposure apparatus is hereinafter referred simply to as an “exposure apparatus”. Reduction in the wavelength of the light output from a light source for exposure is therefore underway. A gas laser apparatus is used as the light source for exposure in place of a mercury lamp used in related art. At present, a KrF excimer laser apparatus, which outputs ultraviolet light having a wavelength of 248 nm, and an ArF excimer laser apparatus, which outputs ultraviolet light having a wavelength of 193 nm, are used as the gas laser apparatus for exposure.

As a current exposure technology, liquid-immersion exposure, in which the gap between the projection lens of the exposure apparatus and a wafer is filled with a liquid, has been put into use. In the liquid-immersion exposure, since the refractive index of the gap between the projection lens and the wafer changes, the apparent wavelength of the light from the light source for exposure shortens. In the liquid-immersion exposure with an ArF excimer laser apparatus as the light source for exposure, a wafer is irradiated with ultraviolet light having an in-water wavelength of 134 nm. The technology described above is called ArF liquid-immersion exposure. The ArF liquid-immersion exposure is also called ArF liquid-immersion lithography.

Since KrF and ArF excimer laser apparatuses each have a wide spectral linewidth ranging from about 350 to 400 pm in spontaneous oscillation, the projection lens of the exposure apparatus produces chromatic aberrations that affect the laser light (ultraviolet light) projected with the size thereof reduced onto the wafer via the projection lens, resulting in a decrease in the resolution. To avoid the decrease in the resolution, the spectral linewidth of the laser light output from the gas laser apparatus needs to be narrow enough to make the chromatic aberrations negligible. The spectral linewidth is also called a spectral width. To achieve a narrow spectral linewidth, a line narrowing module including a line narrowing element is provided in a laser resonator of the gas laser apparatus, and the line narrowing module narrows the spectral width. The line narrowing element may, for example, be an etalon or a grating. A laser apparatus that provides a narrowed spectral width described above is called a narrowed-line laser apparatus.

### CITATION LIST

### Patent Literature

[PTL 1] U.S. Pat. No. 6,078,599B
[PTL 2] US2006/0072636A
[PTL 3] WO2021/015919

### SUMMARY

In an aspect of the present disclosure, a wavelength control method in a laser apparatus including a wavelength actuator configured to cyclically change a wavelength of pulse laser light output in the form of a burst includes reading data on a wavelength target value, determining from the data a first target wavelength and a second target wavelength shorter than the first target wavelength, and setting wavelengths of at least one first-period long wavelength pulse and at least one first-period short wavelength pulse contained in a first period at a start of a burst to a first set wavelength shorter than the first target wavelength and a second set wavelength longer than the second target wavelength, respectively, by using the first target wavelength and the second target wavelength to control the wavelength actuator.

In an aspect of the present disclosure, a laser apparatus includes a wavelength actuator configured to cyclically change a wavelength of pulse laser light output in the form of a burst, and a processor configured to control the wavelength actuator. The processor is configured to read data on a wavelength target value, determine from the data a first target wavelength and a second target wavelength shorter than the first target wavelength, and set wavelengths of at least one first-period long wavelength pulse and at least one first-period short wavelength pulse contained in a first period at a start of a burst to a first set wavelength shorter than the first target wavelength and a second set wavelength longer than the second target wavelength, respectively, by using the first target wavelength and the second target wavelength to control the wavelength actuator.

A method for manufacturing electronic devices according to another aspect of the present disclosure includes causing a laser apparatus to generate pulse laser light, outputting the pulse laser light to an exposure apparatus, and exposing a photosensitive substrate with the pulse laser light in the exposure apparatus to manufacture the electronic devices, the laser apparatus including a wavelength actuator configured to cyclically change a wavelength of pulse laser light output in the form of a burst, and a processor configured to control the wavelength actuator. The processor is configured to read data on a wavelength target value, determine from the data a first target wavelength and a second target wavelength shorter than the first target wavelength, and set wavelengths of at least one first-period long wavelength pulse and at least one first-period short wavelength pulse contained in a first period at a start of a burst to a first set wavelength shorter than the first target wavelength and a second set wavelength longer than the second target wavelength, respectively, by using the first target wavelength and the second target wavelength to control the wavelength actuator.

### BRIEF DESCRIPTION OF THE DRAWINGS

Embodiments of the present disclosure will be described below only by way of example with reference to the accompanying drawings.

FIG. 1 schematically shows the configuration of an exposure system according to Comparative Example.

FIG. 2 schematically shows the configuration of a laser apparatus according to Comparative Example.

FIG. 3 shows an example of a semiconductor wafer exposed to light by the exposure system.

FIG. 4 shows an example of a trigger signal transmitted from an exposure control processor to a laser control processor.

FIG. 5 shows how the position of a scan field changes with respect to the position of pulse laser light.

FIG. 6 shows how the position of the scan field changes with respect to the position of the pulse laser light.

FIG. 7 shows how the position of the scan field changes with respect to the position of the pulse laser light.

FIG. 8 shows how the position of the scan field changes with respect to the position of the pulse laser light.

FIG. 9 is a graph showing a cyclic change in wavelength.

FIG. 10 is a flowchart showing wavelength control processes carried out by the laser control processor in Comparative Example.

FIG. 11 is a flowchart showing the details of the process of determining a target wavelength.

FIG. 12 is a flowchart showing the details of the process of setting a set wavelength used in the laser apparatus in Comparative Example.

FIG. 13 is a graph showing changes in a measured wavelength in a burst output in Comparative Example.

FIG. 14 schematically shows the configuration of the exposure system according to a first embodiment.

FIG. 15 is a graph showing a result of a simulation of the set wavelength near the start of the burst and the measured wavelength measured when the set wavelength is used in the first embodiment.

FIG. 16 shows graphs depicting comparison of the measured wavelength between the first embodiment and Comparative Example.

FIG. 17 is a flowchart showing a wavelength control process carried out by the laser control processor in the first embodiment.

FIG. 18 is a flowchart showing the details of the process of setting the set wavelength used in the laser apparatus in the first embodiment.

FIG. 19 is a graph showing the set wavelength near the start of the burst in a second embodiment.

FIG. 20 schematically shows the configuration of a monitor module used in Comparative Example and the first and second embodiments.

### DETAILED DESCRIPTION

<Contents>
1. Comparative Example
1.1 Exposure system
1.1.1 Configuration
1.1.2 Operation
1.2 Laser apparatus 100
1.2.1 Configuration
1.2.2 Operation
1.3 Line narrowing module 14
1.3.1 Configuration
1.3.2 Operation
1.4 Step-and-scan exposure
1.5 Example of cyclic change in wavelength
1.6 Wavelength control
1.6.1 Primary procedure
1.6.2 Determining target wavelength λ(n)t
1.6.3 Setting set wavelength λin(n)t
1.7 Problems with Comparative Example
2. Laser apparatus in which set wavelength λin(n)t of first pulse in burst is set at value different from target wavelength λ(n)t
2.1 Configuration
2.2 Set wavelength λin(n)t
2.3 Measured wavelength λm(n)
2.4 Wavelength control
2.4.1 Primary procedure
2.4.2 Setting set wavelength λin(n)t
2.5 Effects
3. Example in which absolute value of derivative of function used to set each of first set wavelength λin1(n)t and second set wavelength λin2(n)t decreases over time
4. Others
4.1 Configuration of monitor module 17
4.2 Operation of monitor module 17
4.3 Supplements

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same component has the same reference character, and no redundant description of the same component will be made.

### 1. Comparative Example

### 1.1 Exposure System

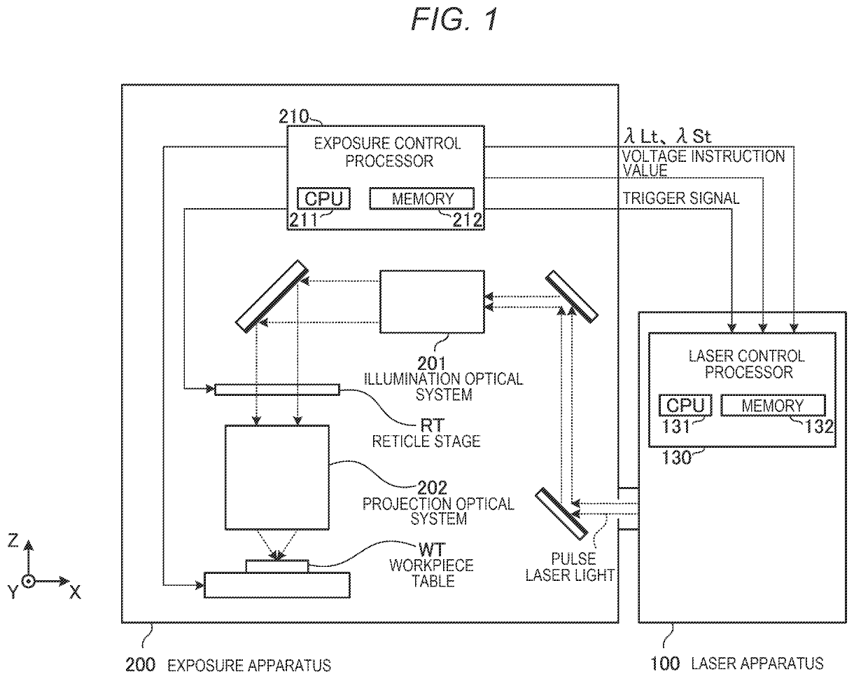

FIG. 1 schematically shows the configuration of an exposure system according to Comparative Example. Comparative Example in the present disclosure is an aspect that the applicant is aware of as known only by the applicant, and is not a publicly known example that the applicant is self-aware of.

The exposure system includes a laser apparatus 100 and an exposure apparatus 200. FIG. 1 shows the laser apparatus 100 in a simplified form.

The laser apparatus 100 includes a laser control processor 130. The laser control processor 130 is a processing apparatus including a memory 132, which stores a control program, and a CPU (central processing unit) 131, which executes the control program. The laser control processor 130 is particularly configured or programmed to carry out a variety of processes included in the present disclosure. The laser control processor 130 corresponds to the processor in the present disclosure. The laser apparatus 100 is configured to output pulse laser light toward the exposure apparatus 200.

### 1.1.1 Configuration

The exposure apparatus 200 includes an illumination optical system 201, a projection optical system 202, and an exposure control processor 210, as shown in FIG. 1.

The illumination optical system 201 illuminates a reticle pattern of a reticle that is not shown but is placed on a reticle stage RT with the pulse laser light incident thereon from the laser apparatus 100.

The projection optical system 202 performs reduction projection on the pulse laser light having passed through the reticle to bring the pulse laser light into focus on a workpiece that is not shown but is placed on a workpiece table WT. The workpiece is a photosensitive substrate, such as a semiconductor wafer onto which a photoresist has been applied in the form of a film.

The exposure control processor 210 is a processing apparatus including a memory 212, which stores a control program, and a CPU 211, which executes the control program. The exposure control processor 210 is particularly configured or programmed to carry out a variety of processes included in the present disclosure. The exposure control processor 210 administers the control on the exposure apparatus 200 and transmits and receives a variety of parameters and signals to and from the laser control processor 130.

### 1.1.2 Operation

The exposure control processor 210 transmits the variety of parameters including a target long wavelength λLt, a target short wavelength λSt, and a voltage instruction value, and a trigger signal to the laser control processor 130. The laser control processor 130 controls the laser apparatus 100 in accordance with the parameters and the signal. The target long wavelength λLt and the target short wavelength λSt are wavelength target values, the target long wavelength λLt corresponding to the first target wavelength in the present disclosure, the target short wavelength λSt corresponding to the second target wavelength in the present disclosure.

The exposure control processor 210 translates the reticle stage RT and the workpiece table WT in opposite directions in synchronization with each other. The workpiece is thus exposed to the pulse laser light having reflected the reticle pattern. The exposure step described above transfers the reticle pattern to the semiconductor wafer. The following multiple steps allow manufacture of electronic devices.

### 1.2 Laser Apparatus 100

### 1.2.1 Configuration

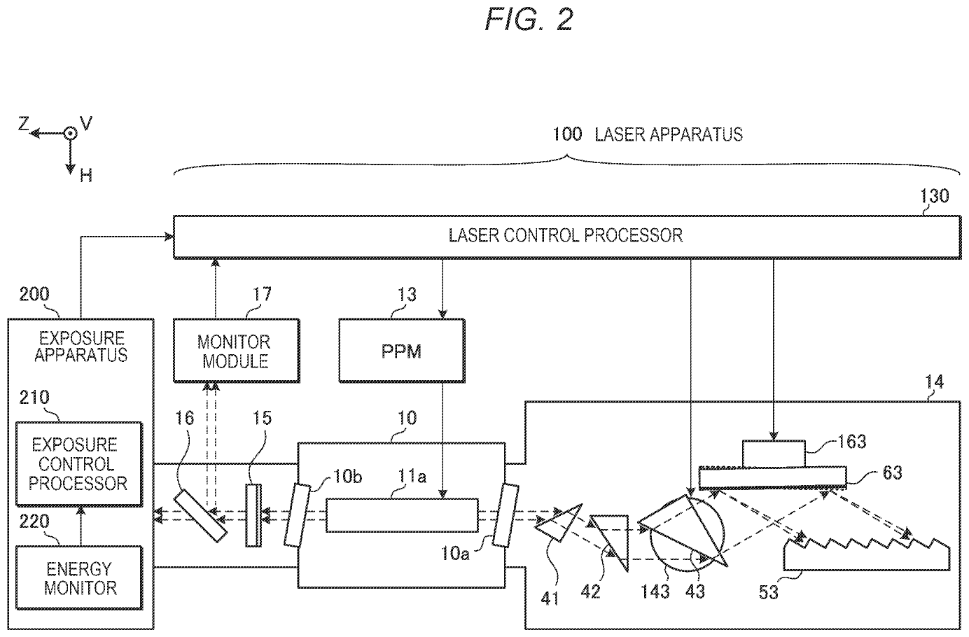

FIG. 2 schematically shows the configuration of the laser apparatus 100 according to Comparative Example. FIG. 2 shows the exposure apparatus 200 in a simplified form.

The laser apparatus 100 includes a laser chamber 10, a pulse power module (PPM) 13, a line narrowing module 14, an output coupling mirror 15, and a monitor module 17 as well as the laser control processor 130. The line narrowing module 14 and the output coupling mirror 15 constitute an optical resonator.

The laser chamber 10 is disposed in the optical path of the optical resonator. The laser chamber 10 is provided with windows 10a and 10b.

The laser chamber 10 accommodates a discharge electrode 11a and a discharge electrode that is not shown but is paired therewith. The discharge electrode that is not shown is located so as to coincide with the discharge electrode 11a in the direction perpendicular to the plane of view of FIG. 2. The laser chamber 10 encapsulates a laser gas containing, for example, an argon or a krypton gas as a rare gas, a fluorine gas as a halogen gas, and a neon gas as a buffer gas.

The pulse power module 13 includes a switch that is not shown and is connected to a charger that is not shown.

The line narrowing module 14 includes prisms 41 to 43, a grating 53 and a mirror 63. The line narrowing module 14 will be described later in detail.

The output coupling mirror 15 includes a partially reflective mirror.

A beam splitter 16 is disposed in the optical path of the pulse laser light output via the output coupling mirror 15, transmits part of the pulse laser light at high transmittance, and reflects the other part of the pulse laser light. The monitor module 17 is disposed in the optical path of the pulse laser light reflected off the beam splitter 16. The configuration of the monitor module 17 will be described later in detail with reference to FIG. 20.

### 1.2.2 Operation

The laser control processor 130 acquires the variety of parameters including the target long wavelength λLt, the target short wavelength λSt, and the voltage instruction value from the exposure control processor 210. The laser control processor 130 transmits a control signal to the line narrowing module 14 based on the target long wavelength λLt and the target short wavelength λSt.

The laser control processor 130 receives the trigger signal from the exposure control processor 210. The laser control processor 130 transmits an oscillation trigger signal based on the trigger signal to the pulse power module 13. The switch provided in the pulse power module 13 is turned on when the pulse power module 13 receives the oscillation trigger signal from the laser control processor 130. When the switch is turned on, the pulse power module 13 generates a pulse-shaped high voltage from the electric energy charged in the charger, and applies the high voltage to the discharge electrode 11a.

When a high voltage is applied to the discharge electrode 11a, discharge occurs in the discharge space between the discharge electrode 11a and the discharge electrode that is not shown. The energy of the discharge excites the laser gas in the laser chamber 10, and the excited laser gas transitions to a high energy level. Thereafter, when the excited laser gas transitions to a low energy level, the laser gas emits light having a wavelength according to the difference between the energy levels.

The light generated in the laser chamber 10 exits out of the laser chamber 10 via the windows 10a and 10b. The light having exited via the window 10a enters the line narrowing module 14. Light having a desired wavelength and therearound out of the light having entered the line narrowing module 14 is deflected back by the line narrowing module 14 and returns to the laser chamber 10.

The output coupling mirror 15 transmits and outputs part of the light having exited via the window 10b and reflects the remaining light back into the laser chamber 10.

The light output from the laser chamber 10 thus travels back and forth between the line narrowing module 14 and the output coupling mirror 15. The light is amplified whenever passing through the discharge space in the laser chamber 10. Furthermore, the light is narrowed in terms of linewidth whenever deflected back by the line narrowing module 14, and becomes light having a steep wavelength distribution having a center wavelength being part of the range of wavelengths selected by the line narrowing module 14. The light thus having undergone the laser oscillation and the line narrowing operation is output as the pulse laser light via the output coupling mirror 15. Unless otherwise specified, the wavelength of the pulse laser light refers to the center wavelength.

The monitor module 17 measures the wavelength of the pulse laser light and transmits a measured wavelength λm(n) to the laser control processor 130. The laser control processor 130 controls the line narrowing module 14 based on the measured wavelength λm(n).

The pulse laser light having passed through the beam splitter 16 enters the exposure apparatus 200. An energy monitor 220 provided in the exposure apparatus 200 may measure the pulse energy of the pulse laser light, and the exposure control processor 210 may set the voltage instruction value based on the measured pulse energy.

### 1.3 Line Narrowing Module 14

### 1.3.1 Configuration

The prisms 41, 42, and 43 are disposed in this order in the optical path of the light beam having exited via the window 10a. The prisms 41 to 43 are so disposed that the surfaces of the prisms 41 to 43 via which the light beam enters the prisms and exits out thereof are all parallel to an axis V, and are supported by holders that are not shown. The prism 43 is rotatable around an axis parallel to the axis V with the aid of a rotary stage 143. An example of the rotary stage 143 may be a rotary stage including a stepper motor and having a large movable range.

The mirror 63 is disposed in the optical path of the light beam having passed through the prisms 41 to 43. The mirror 63 is so disposed that the surface thereof that reflects the light beam is parallel to the axis V, and is rotatable by a rotary stage 163 around an axis parallel to the axis V. An example of the rotary stage 163 may be a highly responsive rotary stage including a piezoelectric element.

Instead, the prisms 42 and 43 may be rotatable by the rotary stages 143 and 163 respectively, and the mirror 63 may not be rotated.

The rotary stages 143 and 163 each correspond to the wavelength actuator in the present disclosure.

The grating 53 is disposed in the optical path of the light beam reflected off the mirror 63. The direction of the grooves of the grating 53 is parallel to the axis V. The grating 53 is supported by a holder that is not shown.

### 1.3.2 Operation

Due to each of the prisms 41 to 43, the light beam having exited via the window 10a is redirected in a plane parallel to a plane HZ, which is a plane perpendicular to the axis V, and the width of the light beam is increased in the plane parallel to the plane HZ.

The light beam having passed through the prisms 41 to 43 is reflected off the mirror 63 and incident on the grating 53.

The light beam incident on the grating 53 is reflected off and diffracted by the plurality of grooves of the grating 53 in the direction according to the wavelength of the light. The grating 53 is disposed in the Littrow arrangement, which causes the angle of incidence of the light beam incident from the mirror 63 on the grating 53 to be equal to the angle of diffraction of the diffracted light having the desired wavelength.

The mirror 63 and the prisms 41 to 43 reduce the beam width of the light having returned from the grating 53 in the plane parallel to the plane HZ, and cause the resultant light to return into the laser chamber 10 via the window 10a.

The laser control processor 130 controls the rotary stages 143 and 163 via drivers that are not shown. The angle of incidence of the light beam incident on the grating 53 changes in accordance with the angles of rotation of the rotary stages 143 and 163, and the wavelength selected by the line narrowing module 14 changes accordingly. The rotary stage 143 is primarily used for coarse adjustment, and the rotary stage 163 is primarily used for fine adjustment.

Based on the target long wavelength λLt and the target short wavelength λSt received from the exposure control processor 210, the laser control processor 130 controls the rotary stage 163 in such a way that the posture of the mirror 63 cyclically changes for each plurality of pulses. The wavelength of the pulse laser light thus cyclically changes from a long wavelength λL to a short wavelength λS and vice versa for each plurality of pulses. The laser apparatus 100 can thus oscillate at the two wavelengths.

The focal length in the exposure apparatus 200 depends on the wavelength of the pulse laser light. The pulse laser light that oscillates at the two wavelengths and enters the exposure apparatus 200 can form images at a plurality of different positions in the direction of the optical path axis of the pulse laser light, so that the depth of focus practically increases. For example, even when a thick photoresist film is exposed to the pulse laser light, the imaging performance can be maintained in the thickness direction of the photoresist film.

### 1.4 Step-and-Scan Exposure

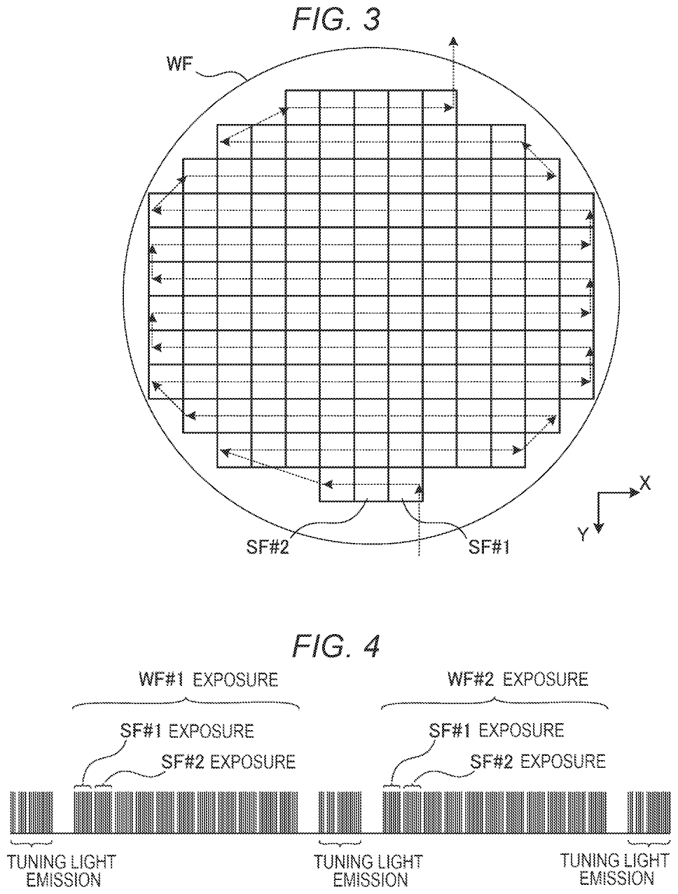

FIG. 3 shows an example of a semiconductor wafer WF exposed to light by an exposure system. The semiconductor wafer WF is, for example, a monocrystalline silicon plate having a substantially disk shape. The semiconductor wafer WF is coated, for example, with a photosensitive resist film. The semiconductor wafer WF is exposed to light on a segment basis, such as scan fields SF #1 and SF #2. The scan fields SF #1 and SF #2 each correspond to a region onto which the reticle pattern of a single reticle is transferred. The numbers #1 and #2 indicate the order of the exposure. The scan fields may not be labeled with the numbers #1, #2, and so on when the description is made with the order of the exposure not specified. The semiconductor wafer WF is so moved that the first scan field SF #1 is irradiated with the pulse laser light, and the scan field SF #1 is exposed thereto. The semiconductor wafer WF is then so moved that the second scan field SF #2 is irradiated with the pulse laser light, and the scan field SF #2 is exposed thereto. Thereafter, all the scan fields SF are exposed to the pulse laser light while the semiconductor wafer WF is moved in the same manner.

FIG. 4 shows an example of the trigger signal transmitted from the exposure control processor 210 to the laser control processor 130. To expose one scan field SF, the pulse laser light is successively output at a predetermined repetition frequency. The successive output of the pulse laser light at a predetermined repetition frequency is called a burst output. To move the scan field from one scan field SF to another scan field SF, the output of the pulse laser light is terminated. The burst output is therefore repeated multiple times to expose one semiconductor wafer WF.

When the exposure of a first semiconductor wafer WF #1 is completed, the output of the pulse laser light to the exposure apparatus 200 is terminated to allow replacement of the semiconductor wafer WF #1 on the workpiece table WT with a second semiconductor wafer WF #2. Note, however, that tuning light emission for the purpose of parameter tuning may be performed with a light shutter that is not shown closed.

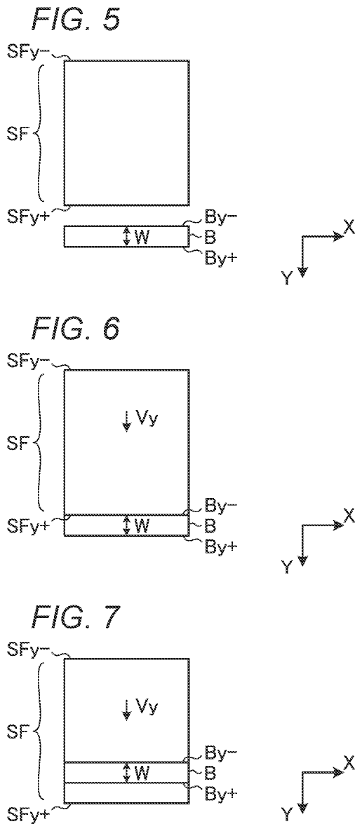

FIGS. 5 to 8 show how the position of a scan field SF changes with respect to the position of the pulse laser light. The axis-X-direction width of the scan field SF is equal to the axis-X-direction width of a beam cross-section B of the pulse laser light at the position of the workpiece table WT. The axis-Y-direction width of the scan field SF is greater than the axis-Y-direction width W of the beam cross-section B of the pulse laser light at the position of the workpiece table WT.

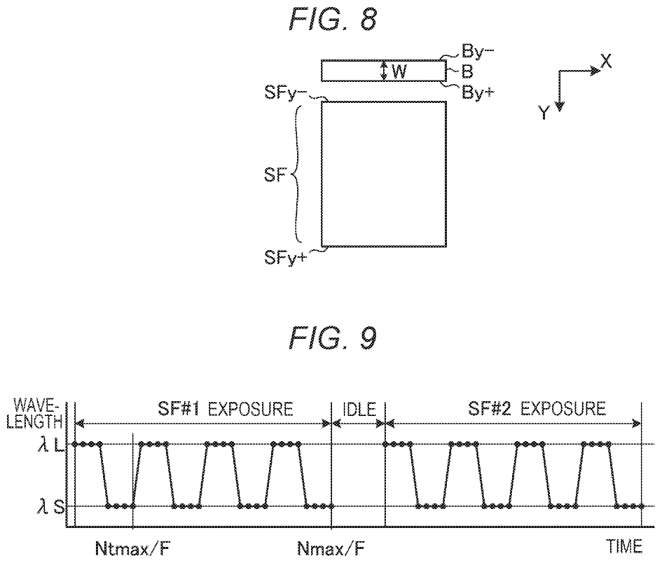

The scan field SF is exposed to the pulse laser light in the order of FIGS. 5, 6, 7, and 8. First, the workpiece table WT is so positioned that an end SFy+ facing the positive end of the Y direction out of the ends of the scan field SF is located at a position separate by a predetermined distance toward the negative end of the Y direction from the position of an end By− facing the negative end of the Y direction out of the ends of the beam cross-section B, as shown in FIG. 5. The workpiece table WT is then accelerated toward the positive end of the Y direction. The speed of the workpiece table WT becomes Vy by the time when the end SFy+ facing the positive end of the Y direction out of the ends of the scan field SF reaches the position of the end By—facing the negative end of the Y direction out of the ends of the beam cross-section B, as shown in FIG. 6. The scan field SF is exposed to the pulse laser light while the workpiece table WT is so moved that the position of the scan field SF makes uniform linear motion at the speed Vy with respect to the position of the beam cross-section B, as shown in FIG. 7. The exposure of the scan field SF is completed when the workpiece table WT is moved until an end SFy− facing the negative end of the Y direction out of the ends of the scan field SF passes through the position of an end By+ facing the positive end of the Y direction out of the ends of the beam cross-section B, as shown in FIG. 8. The exposure is thus performed while the scan field SF is moved with respect to the position of the beam cross-section B.

A period T required for the scan field SF to move at the speed Vy over the distance corresponding to the width W of the beam cross-section B of the pulse laser light is as follows:

T=W/Vy Expression 1

The number of pulses Ns of the pulse laser light radiated to any one location in the scan field SF is equal to the number of pulses of the pulse laser light generated in the required period T and is as follows:

Ns=F·T Expression 2

where F represents the repetition frequency of the pulse laser light.

The number of radiated pulses Ns is also referred to as the number of N slit pulses.

### 1.5 Example of Cyclic Change in Wavelength

FIG. 9 is a graph showing a cyclic change in wavelength. In FIG. 9, the horizontal axis represents the time, and the vertical axis represents the wavelength.

Let Nmax be the number of pulses contained in one burst output to which one scan field SF is exposed.

In the example shown in FIG. 9, the wavelength changes cyclically every Ntmax pulses from the long wavelength λL to the short wavelength λS and vice versa. The number of pulses Ntmax corresponding to one cycle of the change in wavelength is preferably an even number. For example, when Ntmax is eight, the wavelength of each of the first four pulses of the laser light, that is, first to fourth pulse laser light is the long wavelength λL, and the wavelength of each of the second four pulses of the laser light, that is, the fifth to eighth pulse laser light is the short wavelength λS. The generation of four pulses each having the long wavelength λL and the generation of four pulses each having the short wavelength λS are then repeated in the same manner. A cycle Tt of the change in wavelength is given by the following expression:

Tt=Nt max/F

It is desirable that the number of pulses Ns of the pulse laser light radiated to any one location in the scan field SF is a multiple of the number of pulses Ntmax corresponding to one cycle of the change in wavelength. Any portion of the scan field SF is thus irradiated with the pulse laser light by the number of radiated pulses Ns each having the same average wavelength. High-quality electronic devices can thus be manufactured with only a small amount of exposure variation depending on the radiation position.

### 1.6 Wavelength Control

### 1.6.1 Primary Procedure

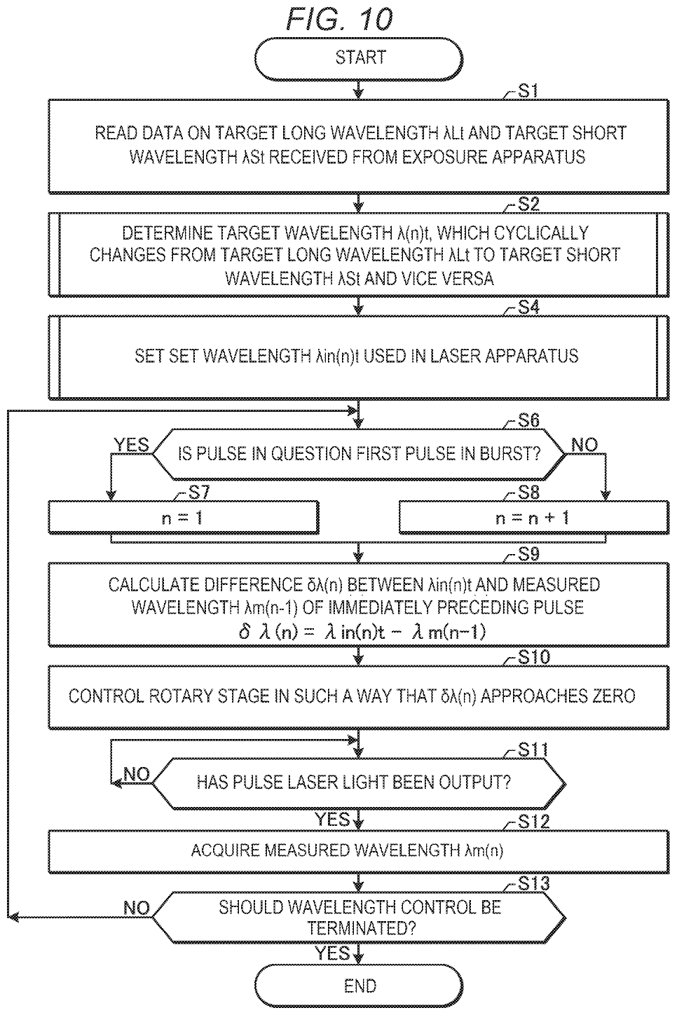

FIG. 10 is a flowchart showing wavelength control processes carried out by the laser control processor 130 in Comparative Example.

In S1, the laser control processor 130 reads data on the target long wavelength λLt and the target short wavelength λSt received from the exposure apparatus 200.

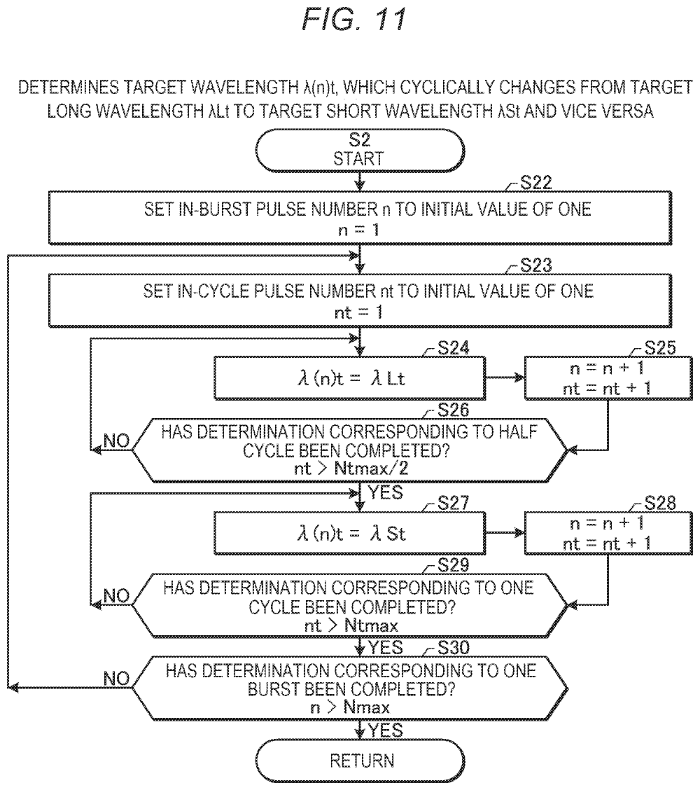

In S2, the laser control processor 130 determines a target wavelength λ(n)t, which changes cyclically from the target long wavelength λLt to the target short wavelength λSt and vice versa. The variable n is an integer ranging from one to Nmax, and Nmax target wavelengths λ(n)t are determined in S2. In the following description, n may be referred to as an in-burst pulse number. Details of S2 will be described later with reference to FIG. 11.

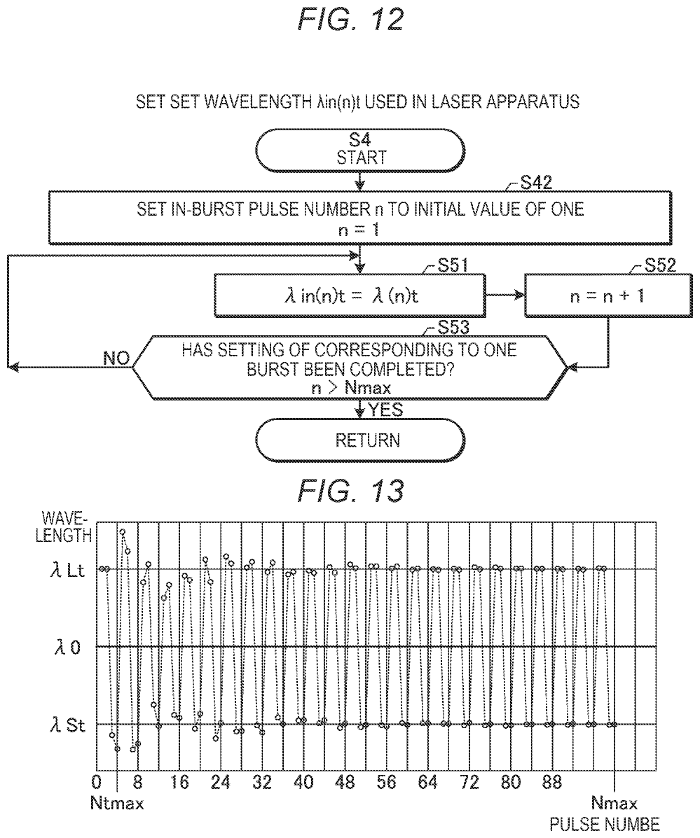

In S4, the laser control processor 130 sets a set wavelength λin(n)t used in the laser apparatus 100. Also, in S4, Nmax set wavelengths λin(n)t are set. Details of S4 will be described later with reference to FIG. 12.

The processes from S6 to S13 are repeated on a pulse basis.

In S6, the laser control processor 130 determines whether the following pulse is the first pulse in the burst. For example, when at least 0.1 second has elapsed since the immediately preceding pulse was output, the laser control processor 130 may determine that the following pulse is the first pulse in the burst. When the following pulse is the first pulse in the burst (YES in S6), the laser control processor 130 sets the in-burst pulse number n to one in S7. When the following pulse is not the first pulse in the burst (NO in S6), the laser control processor 130 adds one to the value of the in-burst pulse number n to update the in-burst pulse number n in S8. After S7 or S8, the laser control processor 130 proceeds to the process in S9.

In S9, the laser control processor 130 calculates a difference δλ(n) between the set wavelength λin(n)t and a measured wavelength λm(n−1) of the immediately preceding pulse by using the following expression:

δλ(n)=λin(n)t−λm(n−1)

The measured wavelength λm(n−1) of the immediately preceding pulse having the in-burst pulse number n of one may be the measured wavelength of the last pulse in the immediately preceding burst output, or the average of the target long wavelength λLt and the target short wavelength λSt.

In S10, the laser control processor 130 controls the rotary stages 143 and 163 in such a way that the difference δλ(n) approaches zero. The control in S10 may be PID control, which is the combination of proportional control, integral control, and derivative control.

In S11, the laser control processor 130 determines whether the pulse laser light has been output. When the pulse laser light has not been output (NO in S11), the laser control processor 130 waits until the pulse laser light has been output. When the pulse laser light is output (YES in S11), the laser control processor 130 proceeds to the process in S12.

In S12, the laser control processor 130 acquires the measured wavelength λm(n) from the monitor module 17. The laser control processor 130 may calculate the difference between the target wavelength λ(n)t and the measured wavelength λm(n) as a wavelength error and output the result to the exposure apparatus 200.

In S13, the laser control processor 130 determines whether the wavelength control should be terminated. For example, when a new target long wavelength λLt and a new target short wavelength λSt are received from the exposure apparatus 200, the laser control processor 130 terminates the wavelength control (YES in S13) and terminates the entire processes of the present flowchart. When the wavelength control should not be terminated (NO in S13), the laser control processor 130 returns to the process in S6.

### 1.6.2 Determining Target Wavelength λ(n)t

FIG. 11 is a flowchart showing the details of the process of determining the target wavelength λ(n)t. The processes shown in FIG. 11 correspond to the subroutine labeled with S2 in FIG. 10. The laser control processor 130 carries out the processes below to alternately set the target wavelength λ(n)t from the target long wavelength λLt to the target short wavelength λSt and vice versa.

In S22, the laser control processor 130 sets the in-burst pulse number n to an initial value of one.

In S23, the laser control processor 130 sets an in-cycle pulse number nt to the initial value of one. The in-cycle pulse number nt is an integer ranging from one to Ntmax, and is a number that identifies the individual pulses within one cycle of the change in wavelength.

In S24, the laser control processor 130 sets the target wavelength λ(n)t to the target long wavelength λLt.

In S25, the laser control processor 130 adds one to each of the in-burst pulse number n and the in-cycle pulse number nt to update these values.

In S26, the laser control processor 130 determines whether the determination of the target wavelength λ(n)t corresponding to half the cycle has been completed. When the in-cycle pulse number nt is smaller than or equal to half the number of pulses Ntmax corresponding to one cycle of the change in wavelength, the laser control processor 130 determines that the determination of the target wavelength λ(n)t corresponding to half the cycle has not been completed (NO in S26), and the laser control processor 130 returns to the process in S24. When the in-cycle pulse number nt is greater than half the number of pulses Ntmax corresponding to one cycle of the change in wavelength, the laser control processor 130 determines that the determination of the target wavelength λ(n)t corresponding to half the cycle has been completed (YES in S26), and the laser control processor 130 proceeds the process in S27.

In S27, the laser control processor 130 sets the target wavelength λ(n)t to the target short wavelength λSt.

In S28, the laser control processor 130 adds one to each of the in-burst pulse number n and the in-cycle pulse number nt to update these values.

In S29, the laser control processor 130 determines whether the determination of the target wavelength λ(n)t corresponding to one cycle has been completed. When the in-cycle pulse number nt is smaller than or equal to the number of pulses Ntmax corresponding to one cycle of the change in wavelength, the laser control processor 130 determines that the determination of the target wavelength λ(n)t corresponding to one cycle has not been completed (NO in S29), and the laser control processor 130 returns to the process in S27. When the in-cycle pulse number nt is greater than the number of pulses Ntmax corresponding to one cycle of the change in wavelength, the laser control processor 130 determines that the determination of the target wavelength λ(n)t corresponding to one cycle has been completed (YES in S29), and the laser control processor 130 proceeds the process in S30.

In S30, the laser control processor 130 determines whether the determination of the target wavelength λ(n)t corresponding to one burst has been completed. When the in-burst pulse number n is smaller than or equal to the number of pulses Nmax corresponding to one burst output, the laser control processor 130 determines that the determination of the target wavelength λ(n)t corresponding to one burst has not been completed (NO in S30), and the laser control processor 130 returns to the process in S23. When the in-burst pulse number n is greater than the number of pulses Nmax corresponding to one burst output, the laser control processor 130 determines that the determination of the target wavelength λ(n)t corresponding to one burst has been completed (YES in S30), and the laser control processor 130 terminates the entire processes of the present flowchart, and returns to the processes shown in FIG. 10.

### 1.6.3 Setting Set Wavelength λin(n)t

FIG. 12 is a flowchart showing the details of the process of setting the set wavelength λin(n)t used in the laser apparatus 100 in Comparative Example. The processes shown in FIG. 12 correspond to the subroutine labeled with S4 in FIG. 10. The laser control processor 130 carries out the processes below to set the set wavelength λin(n)t to the same value as the target wavelength λ(n)t.

In S42, the laser control processor 130 sets the in-burst pulse number n to an initial value of one.

In S51, the laser control processor 130 sets the set wavelength λin(n)t to the same value as the target wavelength λ(n)t.

In S52, the laser control processor 130 adds one to the in-burst pulse number n to update the value of the in-burst pulse number n.

In S53, the laser control processor 130 determines whether the setting of the set wavelength λin(n)t corresponding to one burst has been completed. When the in-burst pulse number n is smaller than or equal to the number of pulses Nmax corresponding to one burst output, the laser control processor 130 determines that the setting of the set wavelength λin(n)t corresponding to one burst has not been completed (NO in S53), and the laser control processor 130 returns to the process in S51. When the in-burst pulse number n is greater than the number of pulses Nmax corresponding to one burst output, the laser control processor 130 determines that the setting of the set wavelength λin(n)t corresponding to one burst has been completed (YES in S53), and the laser control processor 130 terminates the entire processes of the present flowchart, and returns to the processes shown in FIG. 10.

### 1.7 Problems with Comparative Example

FIG. 13 is a graph showing changes in the measured wavelength λm(n) in the burst output in Comparative Example. In FIG. 13, the horizontal axis represents the pulse number, and the vertical axis represents the wavelength. The pulse number increases over time. When the laser control processor 130 attempts to switch the wavelength from the target long wavelength λLt to the target short wavelength λSt and vice versa, the measured wavelength λm(n) may greatly deviate from the target wavelength λ(n)t near the start of the burst. Conceivable causes of the wavelength error may include the hysteresis characteristics of the rotary stage 163, the natural vibration and thermal characteristic fluctuations of the line narrowing module 14, and other factors. When the wavelength is switched at high speed, in particular, the wavelength error is not readily reduced in some cases. The wavelength error may make it difficult to perform highly precise two-wavelength exposure.

In some embodiments described below, the number of non-exposure pulses Nnex including a plurality of pulses at the start of a burst is received from the exposure apparatus 200, and the wavelength error is reduced while the pulse laser light is generated by the number of non-exposure pulses Nnex.

2. Laser apparatus in which set wavelength λin(n)t of first pulse in burst is set at value different from target wavelength λ(n)t

### 2.1 Configuration

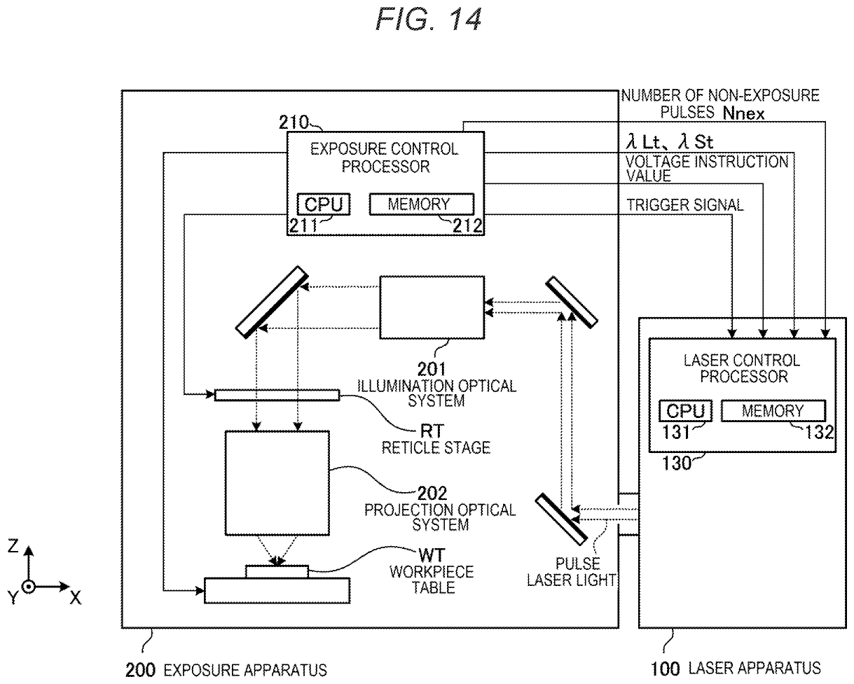

FIG. 14 schematically shows the configuration of the exposure system according to a first embodiment. In the first embodiment, the laser control processor 130 receives the number of non-exposure pulses Nnex from the exposure control processor 210.

The number of non-exposure pulses Nnex is the number of pulses generated in the period from the start of the burst output in FIG. 5 to the time when the end By—facing the negative end of the Y direction out of the ends of the beam cross-section B coincides with the end SFy+ facing the positive end of the Y direction out of the ends of the scan field SF in FIG. 6. The pulse laser light including the pulses from the first pulse at the start of the burst to the Nnex-th pulse, that is, the pulse corresponding to the number Nnex of non-exposure pulses, is not radiated to the scan field SF and is therefore not used for exposure. In the following description, the pulse laser light including the pulses from the first pulse at the start of the burst to the Nnex-th pulse, that is, the pulse corresponding to the number Nnex of non-exposure pulses, may be referred to as non-exposure pulses, and the period for which the non-exposure pulses are output may be referred to as a non-exposure period. The non-exposure period corresponds to the first period in the present disclosure.

The number of non-exposure pulses Nnex is specified by the exposure apparatus 200. Note, however, that a predetermined number of non-exposure pulses Nnex may be stored in the memory 132 of the laser control processor 130.

The pulse laser light having the pulse numbers after the number of non-exposure pulses Nnex is radiated to the scan field SF and used for exposure. In the following description, the pulse laser light having the pulse numbers after the number of non-exposure pulses Nnex may be referred to as exposure pulses, and the period for which the exposure pulses are output may be referred to as an exposure period. The exposure period corresponds to the second period in the present disclosure.

The other points of the configuration in the first embodiment are the same as those in Comparative Example.

### 2.2 Set Wavelength λin(n)t

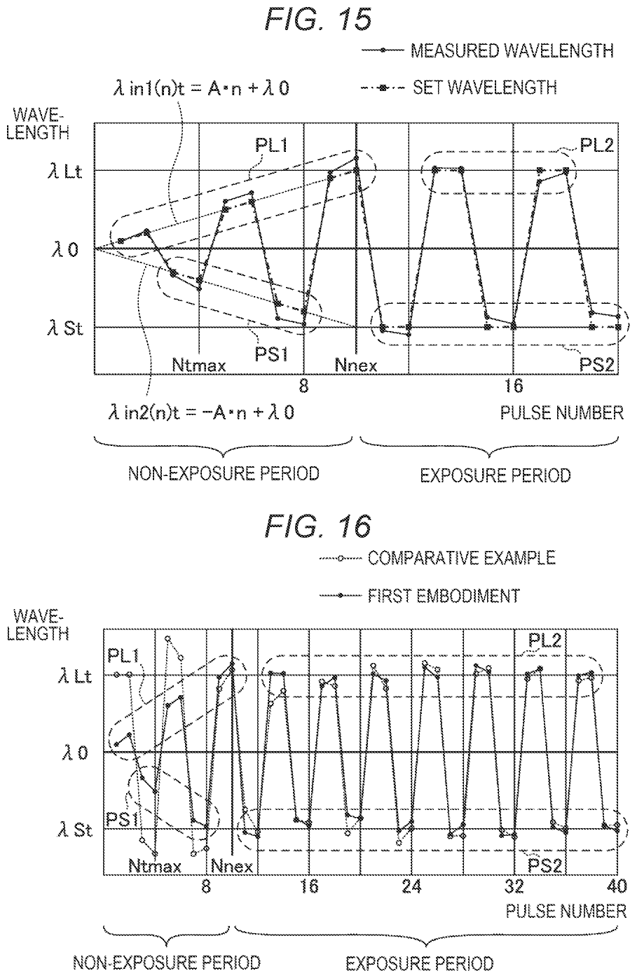

FIG. 15 is a graph showing a result of a simulation of the set wavelength λin(n)t near the start of the burst and the measured wavelength λm(n) measured when the set wavelength λin(n)t is used in the first embodiment. In FIG. 15, the horizontal axis represents the pulse number, and the vertical axis represents the wavelength.

In the first embodiment, the set wavelength λin(n)t of the pulse laser light is set as described below.

(1) The set wavelength λin(n)t in the non-exposure period at the start of the burst includes a first set wavelength λin1(n)t shorter than the target long wavelength λLt and a second set wavelength λin2(n)t longer than the target short wavelength λSt. Since the first set wavelength λin1(n)t and the second set wavelength λin2(n)t provide a wavelength difference smaller than that between the target long wavelength λLt and the target short wavelength λSt, the wavelength switching control is readily performed. Setting the wavelength of the pulse laser light in the non-exposure period to the first set wavelength λin1(n)t and the second set wavelength λin2(n)t therefore allows suppression of occurrence of a large wavelength error at the start of the burst.

(2) The second set wavelength λin2(n)t is shorter than the first set wavelength λin1(n)t.

(3) The pulse laser light output during the exposure period contains a plurality of second-period long wavelength pulses PL2 having a wavelength set to the target long wavelength λLt and output, and a plurality of second-period short wavelength pulses PS2 having a wavelength set to the target short wavelength λSt and output.

(4) The first set wavelength λin1(n)t and the second set wavelength λin2(n)t are so set that the wavelength difference therebetween increases over time.

When the wavelength is switched between the target long wavelength λLt and the target short wavelength λSt from the very start of the burst, as in Comparative Example, a large wavelength error may occur, and it may take time until stable wavelength control is achieved, and reducing the wavelength difference at the start of the burst allows suppression of the wavelength error. Furthermore, increasing the wavelength difference over time allows the wavelength to approach the target long wavelength λLt and the target short wavelength λSt with the wavelength error suppressed.

(5) The first set wavelength λin1(n)t increases over time, and the second set wavelength λin2(n)t decreases over time.

(6) The first set wavelength λin1(n)t is set by using a monotonically increasing function, and the second set wavelength λin2(n)t is set by using a monotonically decreasing function.

(7) The function used to set the first set wavelength λin1(n)t is a function that provides values that approach the target long wavelength λLt over time, and the function used to set the second set wavelength λin2(n)t is a function that provides values that approach the target short wavelength λSt over time.

(8) The function used to set the first set wavelength λin1(n)t is a function that provides values that start with an average λ0 of the target long wavelength λLt and the target short wavelength λSt and approach the target long wavelength λLt, and the function used to set the second set wavelength λin2(n)t is a function that provides values that start with the average λ0 and approach the target short wavelength λSt.

(9) The first set wavelength λin1(n)t is set by using a linear function having a positive gradient, and the second set wavelength λin2(n)t is set by using a linear function having a negative gradient.

For example, the first set wavelength λin1(n)t and the second set wavelength λin2(n)t are set as follows:

λin1(n)t=A·n+λ0 Expression 3

λin2(n)t=−A·n+λ0 Expression 4

In Expressions 3 and 4, A and −A correspond to the gradients of the linear functions, and λ0 corresponds to the intercept of the linear functions.

λ0 is the average of the target long wavelength λLt and the target short wavelength λSt, and is calculated by the following expression:

λ0=(λLt+λSt)/2 Expression 5

A is so calculated by the following expression that the values of Expressions 3 and 4 calculated when the number of non-exposure pulses Nnex is employed are the target long wavelength λLt and the target short wavelength λSt, respectively.

A=(λLt−λSt)/(2·Nnex) Expression 6

(10) The pulse laser light output during the non-exposure period contains a plurality of first-period long wavelength pulses PL1 having a wavelength set to the first set wavelength λin1(n)t and successively output, and a plurality of first-period short wavelength pulses PS1 having a wavelength set to the second set wavelength λin2(n)t and successively output.

For example, in the non-exposure period, the wavelength of two consecutive pulses is set to the first set wavelength λin1(n)t, and the wavelength of other two consecutive pulses is set to the second set wavelength λin2(n)t.

(11) During the non-exposure period, the first set wavelength λin1(n)t is switched to the second set wavelength λin2(n)t and vice versa in the cycle Tt. The cycle Tt corresponds to the first varying cycle in the present disclosure.

(12) The non-exposure period from the first pulse at the start of the burst to the Nnex-th pulse, that is, the pulse corresponding to the number of non-exposure pulses Nnex, is longer than the cycle Tt of the change in wavelength in the non-exposure period.

Changing the wavelength over at least one cycle during the non-exposure period allows stable wavelength control to be achieved before the start of the exposure period.

(13) During the non-exposure period, the pulse laser light including the Ntmax pulses corresponding to one cycle of the change in wavelength is repeatedly output multiple times.

Repeating the change in wavelength multiple times during the non-exposure period allows stable wavelength control to be achieved before the start of the exposure period. Therefore, the number of pulses Ntmax corresponding to one cycle of the change in wavelength is preferably set in accordance with the number of non-exposure pulses Nnex. For example, the number of pulses Ntmax corresponding to one cycle of the change in wavelength is preferably set to an even number by which the number of non-exposure pulses Nnex is divisible.

(14) The pulse laser light output whenever the cycle Tt of the change in wavelength elapses during the non-exposure period contains the plurality of first-period long wavelength pulses PL1 having a wavelength set to the first set wavelength λin1(n)t and successively output, and the plurality of first-period short wavelength pulses PS1 having a wavelength set to the second set wavelength λin2(n)t and successively output.

For example, the number of pulses Ntmax corresponding to one cycle of the change in wavelength is set to four or greater, the wavelength of two consecutive pulses in one cycle being set to the first set wavelength λin1(n)t, the wavelength of the following two consecutive pulses being set to the second set wavelength λin2(n)t.

(15) The set wavelength λin(n)t in the exposure period is set so as to be switched between the target long wavelength λLt and the target short wavelength λSt at a cycle Tt2, as in Comparative Example. The cycle Tt2 corresponds to the second varying cycle in the present disclosure.

(16) The cycle Tt of the change in wavelength in the non-exposure period and the cycle Tt2 of the change in wavelength in the exposure period are the same cycle.

### 2.3 Measured Wavelength λm(n)

Large deviation of the measured wavelength λm(n) at the start of the burst from the set wavelength λin(n) is suppressed, as shown in FIG. 15. Even when the wavelength difference between the first set wavelength λin1(n) and the second set wavelength λin2(n) is gradually increased, the measured wavelength λm(n) precisely follows the set wavelengths. From the start of the exposure period, the measured wavelength λm(n) has a value close to the set wavelength λin(n).

FIG. 16 shows graphs depicting comparison of the measured wavelength λm(n) between the first embodiment and Comparative Example. In FIG. 16, the horizontal axis represents the pulse number, and the vertical axis represents the wavelength. The Nnex pulses at the start of the burst in Comparative Example are assumed in this description to be non-exposure pulses. The wavelength error in the non-exposure period is smaller in the first embodiment than in Comparative Example, so that values closer to the target long wavelength λLt and the target short wavelength λSt are provided with high precision even in the exposure period, as shown in FIG. 16.

### 2.4 Wavelength Control

### 2.4.1 Primary Procedure

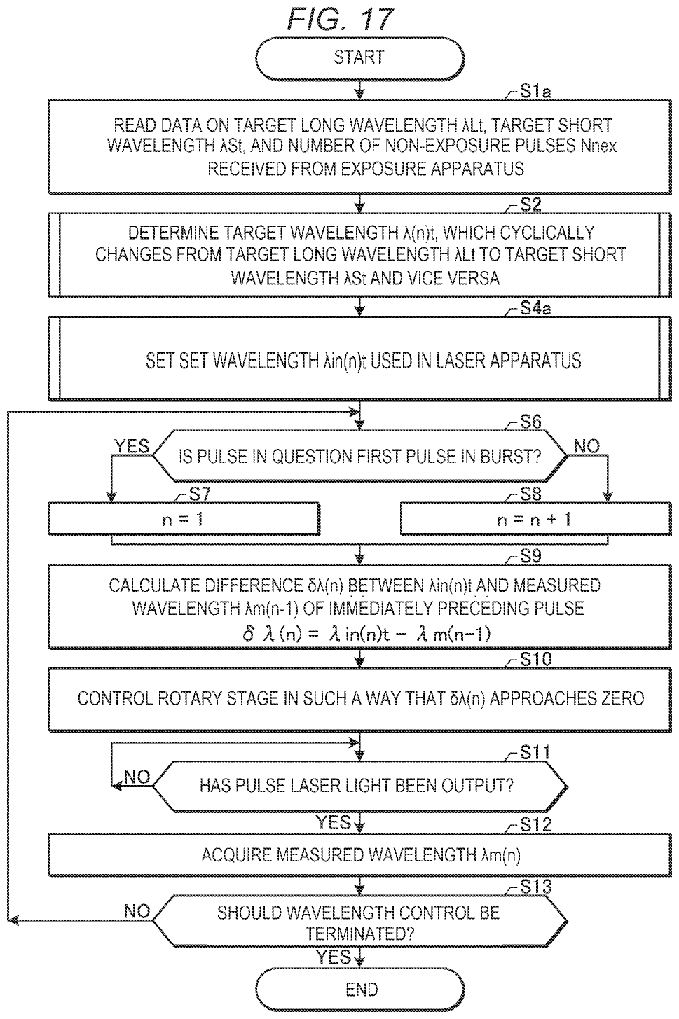

FIG. 17 is a flowchart showing the wavelength control process carried out by the laser control processor 130 in the first embodiment.

In S1a, the laser control processor 130 reads data on the number of non-exposure pulses Nnex as well as the data on the target long wavelength λLt and the target short wavelength λSt received from the exposure apparatus 200.

The process in S2 is the same as that in Comparative Example, and the laser control processor 130 determines the target wavelength λ(n)t, which cyclically changes from the target long wavelength λLt to the target short wavelength λSt and vice versa.

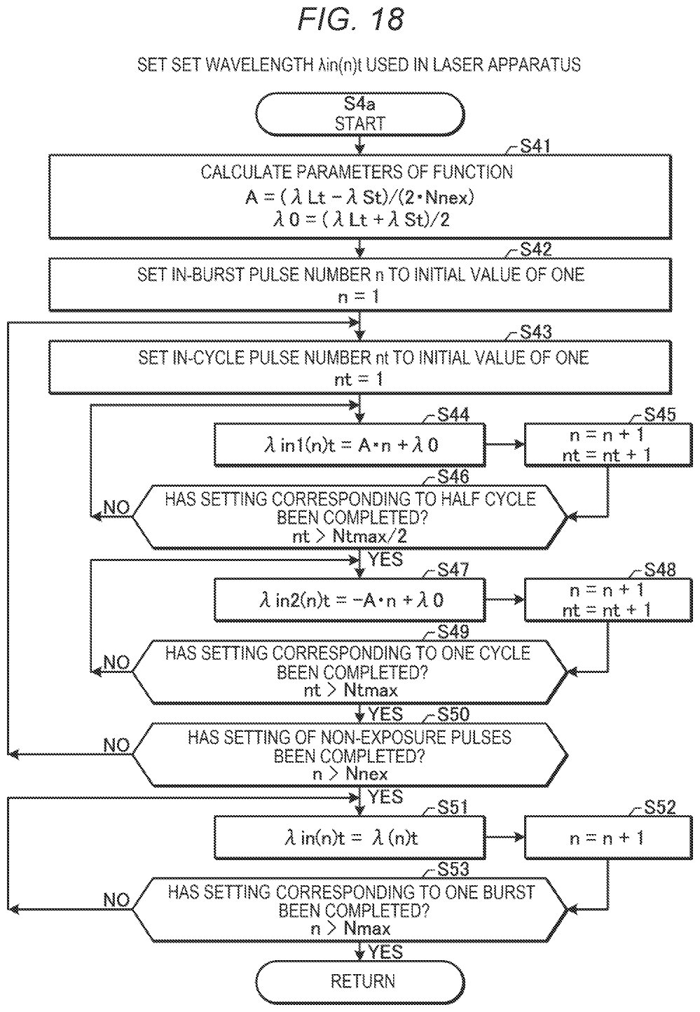

In S4a, the laser control processor 130 sets the set wavelength λin(n)t used in the laser apparatus 100. In S4a, the set wavelengths λin(n)t are so set that those for the non-exposure pulses differ from those for the exposure pulses. The process in S4a will be described later in detail with reference to FIG. 18.

The processes in S6 and the following steps are the same as those in Comparative Example.

### 2.4.2 Setting Set Wavelength λin(n)t

FIG. 18 is a flowchart showing the details of the process of setting the set wavelength λin(n)t used in the laser apparatus 100 in the first embodiment. The processes shown in FIG. 18 correspond to the subroutine labeled with S4a in FIG. 17.

In S41, the laser control processor 130 calculates the parameters A and λ0 of the function used to set the set wavelength λin(n)t by using Expressions 5 and 6 described above.

The process in S42 is the same as that in Comparative Example, and the laser control processor 130 sets the in-burst pulse number n to the initial value of one.

In S43, the laser control processor 130 sets the in-cycle pulse number nt to the initial value of one.

In S44, the laser control processor 130 calculates the first set wavelength λin1(n)t by using Expression 3 described above.

In S45, the laser control processor 130 adds one to each of the in-burst pulse number n and the in-cycle pulse number nt to update these values.

In S46, the laser control processor 130 determines whether the setting of the set wavelength λin(n)t corresponding to half the cycle has been completed. When the in-cycle pulse number nt is smaller than or equal to half the number of pulses Ntmax corresponding to one cycle of the change in wavelength, the laser control processor 130 determines that the set wavelength λin(n)t corresponding to half the cycle has not been set (NO in S46), and the laser control processor 130 returns to the process in S44. When the in-cycle pulse number nt is greater than half the number of pulses Ntmax corresponding to one cycle of the change in wavelength, the laser control processor 130 determines that the setting of the set wavelength λin(n)t corresponding to half the cycle has been completed (YES in S46), and the laser control processor 130 proceeds the process in S47.

In S47, the laser control processor 130 calculates the second set wavelength λin2(n)t by using Expression 4 described above.

In S48, the laser control processor 130 adds one to each of the in-burst pulse number n and the in-cycle pulse number nt to update these values.

In S49, the laser control processor 130 determines whether the setting of the set wavelength λin(n)t corresponding to one cycle has been completed. When the in-cycle pulse number nt is smaller than or equal to the number of pulses Ntmax corresponding to one cycle of the change in wavelength, the laser control processor 130 determines that the setting of the set wavelength λin(n)t corresponding to one cycle has not been completed (NO in S49), and the laser control processor 130 returns to the process in S47. When the in-cycle pulse number nt is greater than the number of pulses Ntmax corresponding to one cycle of the change in wavelength, the laser control processor 130 determines that the setting of the set wavelength λin(n)t corresponding to one cycle has been completed (YES in S49), and the laser control processor 130 proceeds the process in S50.

In S50, the laser control processor 130 determines whether the setting of the set wavelength λin(n)t of the non-exposure pulses has been completed. When the in-burst pulse number n is smaller than or equal to the number of non-exposure pulses Nnex, the laser control processor 130 determines that the setting of the set wavelength λin(n)t of the non-exposure pulses has not been completed (NO in S50), and the laser control processor 130 returns to the process in S43. When the in-burst pulse number n is greater than the number of non-exposure pulses Nnex, the laser control processor 130 determines that the setting of the set wavelength λin(n)t of the non-exposure pulses has been completed (YES in S50), and the laser control processor 130 proceeds to the process in S51. Even when the result of the determination in S50 is NO, execution of S43 to S49 undesirably results in some cases during the execution in the state in which the number of in-burst pulses n is greater than the number of non-exposure pulses Nnex. The state described above includes a case where the number of pulses Ntmax corresponding to one cycle of the change in wavelength has not been set to the number of non-exposure pulses Nnex divided by an integer. Assuming such a case, the same process as that in S50 may be placed after S45 and after S48.

The processes from S51 to S53 are the same as those in Comparative Example, and the laser control processor 130 sets the set wavelength λin(n)t of the exposure pulses to the value equal to the target wavelength λ(n)t until the setting of the set wavelength λin(n)t corresponding to one burst is completed.

### 2.5 Effects

According to the first embodiment, the target long wavelength λLt and the target short wavelength λSt are converted into the first set wavelength λin1(n)t and the second set wavelength λin2(n)t, respectively, to which the set wavelength λin(n)t in the non-exposure period at the start of the burst is set. The effect described above suppresses occurrence of a large wavelength error in the non-exposure period, allows stable two-wavelength control from the start of the exposure period, and improves the exposure performance.

As for the other points, the first embodiment is the same as Comparative Example.

3. Example in which absolute value of derivative of function used to set each of first set wavelength λin1(n)t and second set wavelength λin2(n)t decreases over time

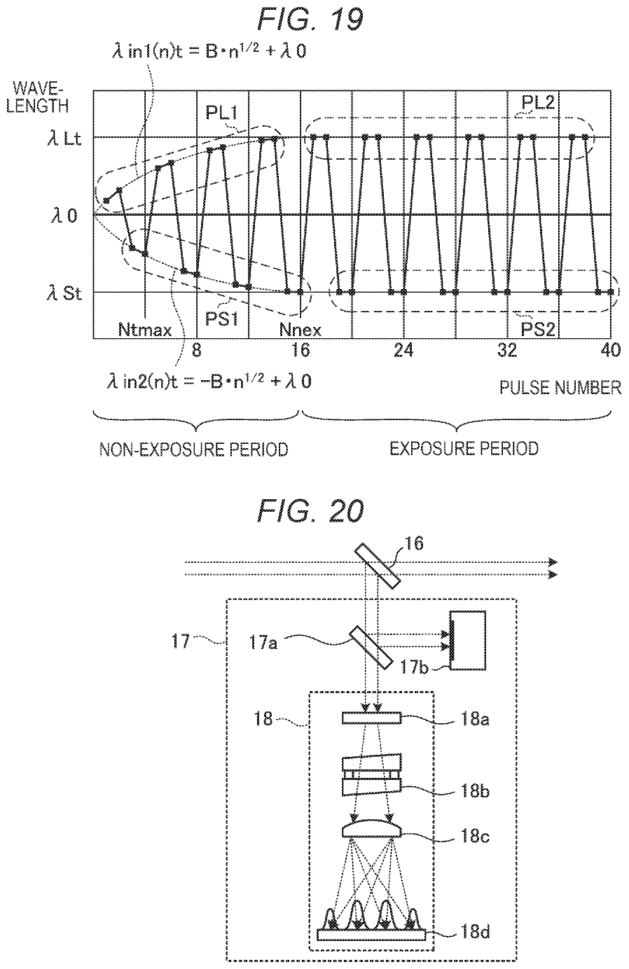

FIG. 19 is a graph showing the set wavelength λin(n)t near the start of the burst in a second embodiment. In FIG. 19, the horizontal axis represents the pulse number, and the vertical axis represents the wavelength.

In the second embodiment, the set wavelength λin(n)t of the pulse laser light in the non-exposure period is set as described below.

The function used to set each of the first set wavelength λin1(n)t and the second set wavelength λin2(n)t is not a linear function but is a function in which the absolute value of the derivative of the function decreases over time. For example, the following functions may be employed.

λin1(n)t=B·n^{1/2}+λ0

λin2(n)t=−B·n^{1/2}+λ0
where B represents a constant so set that the first set wavelength λin1(n)t and the second set wavelength λin2(n)t of the laser light including Nnex non-exposure pulses become the target long wavelength λLt and the target short wavelength λSt, respectively.

The functions used to set the first set wavelength λin1(n)t and the second set wavelength λin2(n)t are not limited to those described above, and may each be a quadratic function that monotonically increases or decreases in the non-exposure period. As for the other points, the second embodiment is the same as first embodiment.

### 4. Others

### 4.1 Configuration of Monitor Module 17

FIG. 20 schematically shows the configuration of the monitor module 17 used in Comparative Example and the first and second embodiments. The monitor module 17 includes a beam splitter 17a, an energy sensor 17b, and an etalon spectrometer 18.

The beam splitter 17a is located in the optical path of the pulse laser light reflected off the beam splitter 16. The energy sensor 17b is located in the optical path of the pulse laser light reflected off the beam splitter 17a.

The etalon spectrometer 18 is disposed in the optical path of the pulse laser light having passed through the beam splitter 17a. The etalon spectrometer 18 includes a diffusion plate 18a, an etalon 18b, a condenser lens 18c, and a line sensor 18d.

The diffusion plate 18a is located in the optical path of the pulse laser light having passed through the beam splitter 17a. The diffusion plate 18a has a large number of irregularities at a surface thereof and is configured to transmit and diffuse the pulse laser light.

The etalon 18b is located in the optical path of the pulse laser light having passed through the diffusion plate 18a. The etalon 18b includes two partially reflective mirrors. The two partially reflective mirrors face each other with an air gap having a predetermined thickness therebetween and are bonded to each other via a spacer.

The condenser lens 18c is located in the optical path of the pulse laser light having passed through the etalon 18b.

The line sensor 18d is located at the focal plane of the condenser lens 18c in the optical path of the pulse laser light having passed through the condenser lens 18c. The line sensor 18d receives interference fringes formed by the etalon 18b and the condenser lens 18c. The interference fringes are an interference pattern produced by the pulse laser light and have a shape of concentric circles, and the square of the distance from the center of the concentric circles is proportional to the change in the wavelength of the pulse laser light.

The line sensor 18d is a light distribution detecting sensor including a large number of light receivers arranged in one dimension. In place of the line sensor 18d, an image sensor including a large number of light receivers arranged two-dimensionally may instead be used as the light distribution detecting sensor. The light receivers are each called a channel. The light intensity distribution of the interference fringes is produced from the light intensity detected at each of the channels.

### 4.2 Operation of Monitor Module 17

The energy sensor 17b detects the pulse energy of the pulse laser light and outputs data on the pulse energy to the laser control processor 130. The data on the pulse energy may be used by the laser control processor 130 to perform feedback control on data used to set the application voltage to be applied to the discharge electrode 11a. The timing at which the data on the pulse energy is received can be used as a reference for the timing at which the laser control processor 130 outputs a data output trigger to the etalon spectrometer 18.

The etalon spectrometer 18 generates the measured waveform from the interference pattern produced by the pulse laser light and detected by the line sensor 18d. The etalon spectrometer 18 transmits the measured waveform to the laser control processor 130 in accordance with the data output trigger output from the laser control processor 130.

The measured waveform is also called a fringe waveform, which indicates the relationship between the distance from the center of the concentric circles, which constitute the interference fringes, and the light intensity.

The laser control processor 130 uses the measured waveform output from the etalon spectrometer 18 to calculate the center wavelength of the pulse laser light as the measured wavelength λm(n). Instead, a controller that is not shown but is accommodated in the etalon spectrometer 18 calculates the measured wavelength λm(n) and transmits the calculated measured wavelength λm(n) to the laser control processor 130. The laser control processor 130 performs feedback control on the center wavelength of the pulse laser light by outputting a control signal to the drivers, which are not shown but drive the rotary stages 143 and 163, based on the set wavelength λin(n)t and the measured wavelength λm(n).

### 4.3 Supplements

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, the term “include” or “included” should be construed as “does not necessarily include only what is described”. The term “have” should be construed as “does not necessarily have only what is described”. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A wavelength control method in a laser apparatus including a wavelength actuator configured to cyclically change a wavelength of pulse laser light output in the form of a burst, the method comprising:
reading data on a wavelength target value;
determining from the data a first target wavelength and a second target wavelength shorter than the first target wavelength; and
setting wavelengths of at least one first-period long wavelength pulse and at least one first-period short wavelength pulse contained in a first period at a start of a burst to a first set wavelength shorter than the first target wavelength and a second set wavelength longer than the second target wavelength, respectively, by using the first target wavelength and the second target wavelength to control the wavelength actuator.

2. The wavelength control method according to claim 1,
wherein the second set wavelength is shorter than the first set wavelength.

3. The wavelength control method according to claim 1,
wherein wavelengths of a plurality of second-period long wavelength pulses and a plurality of second-period short wavelength pulses output during a second period after the first period are set to the first target wavelength and the second target wavelength, respectively, to control the wavelength actuator.

4. The wavelength control method according to claim 1,
wherein pulses output during the first period include the first-period long wavelength pulses including a plurality of pulses and the first-period short wavelength pulses including a plurality of pulses, and
the first set wavelength and the second set wavelength are so set that a wavelength difference therebetween increases over time.

5. The wavelength control method according to claim 4,
wherein the first set wavelength is set so as to increase over time, and the second set wavelength is set so as to decrease over time.

6. The wavelength control method according to claim 5,
wherein the first set wavelength is set by using a monotonically increasing function, and the second set wavelength is set by using a monotonically decreasing function.

7. The wavelength control method according to claim 6,
wherein the monotonically increasing function is a function configured to provide values that approach the first target wavelength over time, and
the monotonically decreasing function is a function configured to provide values that approach the second target wavelength over time.

8. The wavelength control method according to claim 6,
wherein the monotonically increasing function is a function configured to provide values that start with an average of the first target wavelength and the second target wavelength and approach the first target wavelength, and
the monotonically decreasing function is a function configured to provide values that start with the average and approach the second target wavelength.

9. The wavelength control method according to claim 5,
wherein the first set wavelength is set by using a linear function having a positive gradient, and the second set wavelength is set by using a linear function having a negative gradient.

10. The wavelength control method according to claim 1,
wherein the pulse laser light output during the first period includes the first-period long wavelength pulses including a plurality of pulses successively output and the first-period short wavelength pulses including a plurality of pulses successively output.

11. The wavelength control method according to claim 1,
wherein the first set wavelength is switched to the second set wavelength and vice versa in a first varying cycle during the first period to control the wavelength actuator.

12. The wavelength control method according to claim 11,
wherein the first period is longer than the first varying cycle.

13. The wavelength control method according to claim 11,
wherein the switching of the wavelength in the first varying cycle is repeated multiple times during the first period.

14. The wavelength control method according to claim 11,
wherein the pulse laser light output during the first varying cycle includes the first-period long wavelength pulses including a plurality of pulses successively output and the first-period short wavelength pulses including a plurality of pulses successively output.

15. The wavelength control method according to claim 11,
wherein the first target wavelength is switched to the second target wavelength and vice versa in a second varying cycle during a second period after the first period to control the wavelength actuator.

16. The wavelength control method according to claim 15,
wherein the first varying cycle and the second varying cycle are the same cycle.

17. The wavelength control method according to claim 1,
wherein the pulses output during the first period are non-exposure pulses specified by an exposure apparatus connected to the laser apparatus.

18. The wavelength control method according to claim 1,
wherein the pulses output during the second period after the first period are pulses used for exposure performed by an exposure apparatus connected to the laser apparatus.

19. A laser apparatus comprising:
a wavelength actuator configured to cyclically change a wavelength of pulse laser light output in the form of a burst; and
a processor configured to control the wavelength actuator,
the processor being configured to
read data on a wavelength target value,
determine from the data a first target wavelength and a second target wavelength shorter than the first target wavelength, and
sets wavelengths of at least one first-period long wavelength pulse and at least one first-period short wavelength pulse contained in a first period at a start of a burst to a first set wavelength shorter than the first target wavelength and a second set wavelength longer than the second target wavelength, respectively, by using the first target wavelength and the second target wavelength to control the wavelength actuator.

20. A method for manufacturing electronic devices, the method comprising:
causing a laser apparatus to generate pulse laser light;
outputting the pulse laser light to an exposure apparatus; and
exposing a photosensitive substrate with the pulse laser light in the exposure apparatus to manufacture the electronic devices,
the laser apparatus comprising
a wavelength actuator configured to cyclically change a wavelength of pulse laser light output in the form of a burst, and
a processor configured to control the wavelength actuator, the processor being configured to
read data on a wavelength target value,
determine from the data a first target wavelength and a second target wavelength shorter than the first target wavelength, and
set wavelengths of at least one first-period long wavelength pulse and at least one first-period short wavelength pulse contained in a first period at a start of a burst to a first set wavelength shorter than the first target wavelength and a second set wavelength longer than the second target wavelength, respectively, by using the first target wavelength and the second target wavelength to control the wavelength actuator.
